(19) United States
(12) Patent Application Publication
(10) Pub. No.: US 2010/0013037 A1
(43) Pub. Date: Jan. 21, 2010

(54) SOLAR CELL AND MANUFACTURING METHOD THEREOF

(76) Inventors: Min Park, Seoul (KR); Min-Seok Oh, Yongin-si (KR); Myung-Hun Shin, Suwon-si (KR); Czang-Ho Lee, Suwon-si (KR); Byoung-Kyu Lee, Suwon-si (KR); Yuk-Hyun Nam, Goyang-si (KR); Seung-Jae Jung, Seoul (KR); Mi-Hwa Lim, Seocheon-gun (KR); Joon-Young Seo, Seoul (KR)

Correspondence Address: Haynes and Boone, LLP;IP Section, 2323 Victory Avenue, SUITE 700, Dallas, TX, 75219, US

(21) Appl. No.: 12/397,129

(22) Filed: Mar. 3, 2009

(30) Foreign Application Priority Data
Jul. 18, 2008 (KR) 10-2008-0070066

(51) Int. Cl. H01L 31/0224; H01L 31/18

(52) U.S. Cl. 257/431; 438/98

(57) ABSTRACT

A method for manufacturing a solar cell is provided. The manufacturing method includes: depositing a transparent conductive layer on a substrate; patterning the transparent conductive layer; forming a semiconductor layer including deposited on the patterned transparent conductive layer; patterning the semiconductor layer; coating a metal powder on the patterned semiconductor layer; forming a rear electrode layer on the semiconductor layer coated with the metal powder; and patterning the rear electrode layer and the semiconductor layer. This method is useful for producing a solar cell with improved light absorption efficiency.

### CROSS-REFERENCE TO RELATED APPLICATION

This application claims priority to and the benefit of Korean Patent Application No. 10-2008-0070066 filed in the Korean Intellectual Property Office on Jul. 18, 2008, the entire contents of which are incorporated herein by reference.

### BACKGROUND OF THE INVENTION

(a) Field of the Invention

The present invention relates to a solar cell and a manufacturing method thereof.

(b) Description of the Related Art

A solar cell that converts solar light energy into electrical energy generates electricity by using two kinds of semiconductors that are referred to as a P-type semiconductor and an N-type semiconductor. Solar cells largely can be categorized as crystalline silicon solar cells that are used in most commercial products, thin film solar cells that can use an inexpensive substrate, and hybrid solar cells that combine a crystalline silicon solar cell and a thin film solar cell.

In the present invention, a thin film solar cell is formed using a method of coating a film on a thin glass or plastic substrate. Generally, the spread distance of the carrier is shorter in a thin film solar cell than in a crystalline silicon solar cell, and the collection efficiency of electron-hole pairs generated by the solar light is very low when the thin film is only made of a P—N junction structure. Hence, a thin film using a PIN structure, in which the light absorption layer of an intrinsic semiconductor material having high light absorption efficiency is inserted between the P-type and the N-type semiconductors, is applied.

In the general structure of the thin film solar cell, a front transparent conductive layer, a PIN layer, and a rear reflecting electrode layer are deposited in sequence on a substrate. In this structure, the solar light is passed through the front transparent conductive layer and is absorbed in the light absorption layer, and light that is not absorbed in the light absorption layer and thus is passed through the light absorption layer is reflected by the rear reflecting electrode layer and is then absorbed in the light absorption layer.

When the light absorption layer of the solar cell is formed of the thin film type having a thickness of several microns or less, less solar light is absorbed and current density decreases due to light transmission. Accordingly, a light scattering/trapping technique using the front transparent conductive layer and a rear reflecting electrode plays an important role in increasing the efficiency of the solar cell.

To increase the efficiency of the solar cell, the transparent conductive layer may be textured. Also, to improve the light efficiency by increasing the path length of the light, the textured transparent conductive layer may also be positioned between the rear electrode layer and the N layer.

However, the manufacturing process for texturing the transparent conductive layer between the rear electrode layer and the light absorption layer is complicated, and light efficiency may be reduced by the transparent conductive layer having a lower electrical conductivity than the metal of the rear electrode layer. Also, there is an increased possibility of defect generation due to the increased contact interfaces between the layers.

The above information disclosed in this Background section is only for enhancement of understanding of the background of the invention and therefore it may contain information that does not form the prior art that is already known in this country to a person of ordinary skill in the art.

### SUMMARY OF THE INVENTION

Accordingly, the present invention maximizes the light absorption efficiency by increasing the reflectance of the rear electrode layer without reduction of electrical conductivity, and simplifies the manufacturing method.

A manufacturing method of a solar cell according to an exemplary embodiment of the present invention includes: depositing a transparent conductive layer on a substrate; patterning the transparent conductive layer; forming a semiconductor layer deposited on the patterned transparent conductive layer; patterning the semiconductor layer; coating the patterned semiconductor layer with metal powder; forming a rear electrode layer on the semiconductor layer coated with the metal powder; and patterning the rear electrode layer and the semiconductor layer.

In the coating of the metal powder on the patterned semiconductor layer, the metal powder may cover the upper surface and the lateral surface of the patterned semiconductor layer.

The metal powder may be one of silver (Ag), aluminum (Al), titanium (Ti), and alloys thereof.

The metal powder may be made up of particles whose sizes range from 50 nm to 5 μm.

The metal powder may be dispersed in a volatile solvent and coated as a solution, a paste, or an ink on the semiconductor layer.

The coating of the metal powder on the patterned semiconductor layer may be accomplished through use of at least one of spin coating, slit coating, spraying, screen printing, ink-jetting, gravure printing, offset printing, and dispensing.

In the coating of the metal powder on the patterned semiconductor layer, the metal powder may be mixed with an amphiphilic solvent or surfactant and coated on the semiconductor layer.

The amphiphilic solvent or surfactant may be one of ethanol, methanol, acetone, isopropyl alcohol, N-methyl pyrrolidone (NMP), cyclopentanone, and cyclohexanone.

Before the coating of the metal powder on the patterned semiconductor layer, the semiconductor layer may be irradiated by plasma to form protrusions and depressions on the surface of the semiconductor layer.

Before the coating of the metal powder on the patterned semiconductor layer, the semiconductor layer may be heat-treated.

The heat treatment may be executed at a temperature of less than 200 degrees and for a time of less than 30 minutes.

Before the coating of the metal powder on the patterned semiconductor layer, the semiconductor layer may be coated with an adhesive.

Before the patterning of the transparent conductive layer, the upper surface of the transparent conductive layer may be textured.

A manufacturing method of a solar cell according to another exemplary embodiment of the present invention includes: depositing a transparent conductive layer on a substrate; patterning the transparent conductive layer; forming a semiconductor layer deposited on the patterned transparent conductive layer, wherein the semiconductor layer includes a P layer, an I layer, and an N layer; coating the semiconductor layer with metal powder; patterning the semiconductor layer; forming a rear electrode layer on the patterned semiconductor layer; and patterning the rear electrode layer and the semiconductor layer.

Before patterning the transparent conductive layer, the upper surface of the transparent conductive layer may be textured.

In the coating of the metal powder on the semiconductor layer, the metal powder may be mixed with an amphiphilic solvent or surfactant and the semiconductor layer may be coated with the metal power.

The amphiphilic solvent or surfactant may be one of ethanol, methanol, acetone, isopropyl alcohol, N-methyl pyrrolidone (NMP), cyclopentanone, and cyclohexanone.

A solar cell according to another exemplary embodiment of the present invention includes: a substrate; a transparent conductive layer deposited on the substrate; a semiconductor layer deposited on the transparent conductive layer; metal powder coated on the semiconductor layer; a contact hole formed in the semiconductor layer; and a rear electrode layer filling in the contact hole and covering the semiconductor layer.

The metal powder may be coated on the lateral surface of the semiconductor layer exposed by the contact hole.

The metal powder may be made of one of gold, aluminum, titanium, and alloys thereof.

The metal powder may be mixed with an amphiphilic solvent or surfactant and coated on the semiconductor layer.

The semiconductor layer includes a P layer, an I layer, and an N layer.

A solar cell according to another exemplary embodiment of the present invention includes: a substrate; a reflecting electrode layer deposited on the substrate; metal powder coated on the reflecting electrode layer; a semiconductor layer deposited on the reflecting electrode layer coated with the metal powder; and a rear electrode layer deposited on the semiconductor layer.

A connection electrode formed on the rear electrode layer may be further included.

According to the present invention, a metal powder is coated on a light absorption layer such that reflectance of the rear reflecting electrode is increased and reflectance of the light absorbed in the lateral side is increased, thereby maximizing the light absorption amount.

### BRIEF DESCRIPTION OF THE DRAWINGS

FIG. 1 to FIG. 7 are cross-sectional views sequentially showing the manufacturing process in a manufacturing method of a solar cell according to an exemplary embodiment of the present invention.

FIG. 8 to FIG. 11 are cross-sectional views sequentially showing the manufacturing process in a manufacturing method of a solar cell according to another exemplary embodiment of the present invention.

FIG. 12 are cross-sectional views showing a solar cell according to another exemplary embodiment of the present invention.

### DETAILED DESCRIPTION OF THE EMBODIMENTS

An exemplary embodiment of the present invention will hereinafter be described in detail with reference to the accompanying drawings. As those skilled in the art would realize, the described embodiments may be modified in various ways, all without departing from the spirit or scope of the present invention. The present exemplary embodiments provide complete disclosure of the nature and scope of the present invention to those skilled in the art.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element, or intervening elements may also be present.

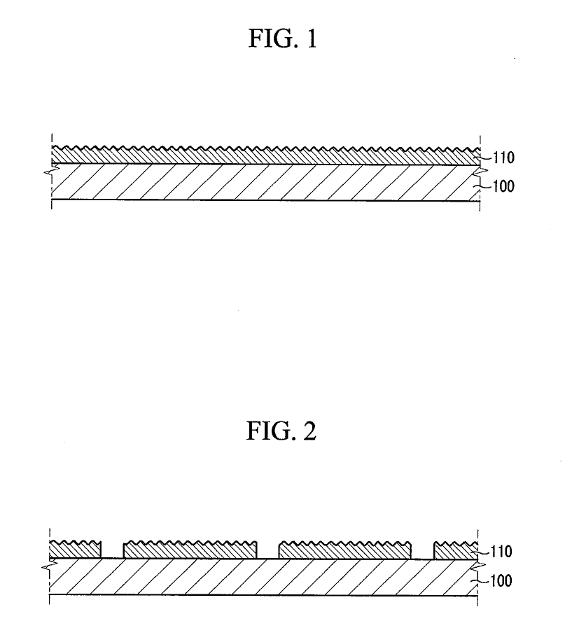

FIG. 1 to FIG. 7 are cross-sectional views sequentially showing the manufacturing process in a manufacturing method of a solar cell according to an exemplary embodiment of the present invention.

First, as shown in FIG. 1, a transparent conductive layer 110 is deposited on a substrate 100, and the surface thereof is texture-treated. The transparent conductive layer 110 may be made of SnO₂, ZnO:Al, ZnO:B, ITO (indium tin oxide), or IZO (indium zinc oxide). Texturing the surface of the transparent conductive layer 110, such that the surface of the transparent conductive layer 110 is uneven, increases the effective absorption amount of solar light by the solar cell by reducing light reflection at the surface where the solar light is incident.

Next, as shown in FIG. 2, the transparent conductive layer 110 is patterned by laser scribing.

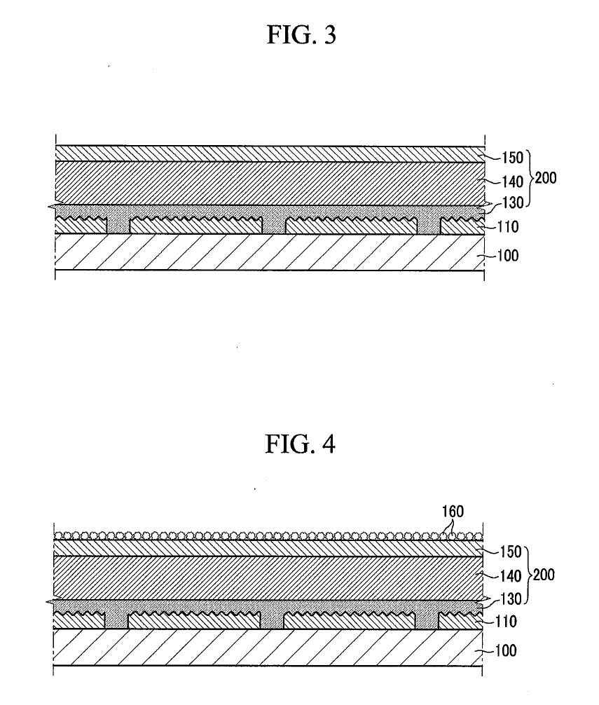

Next, as shown in FIG. 3, a P layer 130, an I layer 140, and an N layer 150 are sequentially deposited on the patterned transparent conductive layer 110 to form a semiconductor layer 200. The P layer 130, the I layer 140, and the N layer 150 may be deposited by plasma enhanced chemical vapor deposition (PECVD).

Next, as shown in FIG. 4, a metal powder 160 is coated on the semiconductor layer 200.

The method used to coat the metal powder 160 on the semiconductor layer 200 may be one of spin coating, slit coating, spraying, screen printing, ink-jetting, gravure printing, offset printing, and dispensing. To coat the metal powder 160 on the semiconductor layer 200 by using these methods, the metal powder 160 is dispersed in a solvent having high volatility so as not to affect the metal power 160 and the different layers, and is coated as a solution, a paste, or an ink on the semiconductor layer 200.

The dispersion agent used to coat the metal powder 160 on the semiconductor layer 200 may be an amphiphilic solvent or surfactant. The amphiphilic solvent or surfactant is a material simultaneously being hydrophilic and hydrophobic such that the characteristics of the material are determined according to its environment.

The amphiphilic solvent or surfactant may be ethanol, methanol, acetone, isopropyl alcohol, N-methyl pyrrolidone (NMP), cyclopentanone, or cyclohexanone. Among them, N-methyl pyrrolidone (NMP), cyclopentanone, or cyclohexanone may be preferred.

Here, the amphiphilic solvent or surfactant may function as a hydrophilic solvent, whereby the metal powder 160 is mixed with the hydrophilic solvent so as to enclose the surface of the particles of the metal powder 160 with the hydrophilic solvent, such that the metal powder 160 may be easily adsorbed onto the surface of the semiconductor layer 200, and also that the metal powder 160 particles do not coagulate.

To improve the adhesion between the metal powder 160 and the semiconductor layer 200, the following method may be applied.

Before coating the semiconductor 200 with the metal powder 160, the semiconductor layer 200 is irradiated with hydrogen plasma or argon plasma to form protrusions and depressions on the surface of the semiconductor layer 200.

Adhesive force may be improved by using an adhesion promoter or an additive that does not have an interaction reaction with the semiconductor layer 200 and the metal powder 160.

Also, before coating the metal powder 160, the semiconductor layer 200 may be heat-treated for a short time (e.g., less than 30 minutes) at a low temperature (e.g., less than 200 degrees) to increase the adhesive force between the metal powder 160 and the semiconductor layer 200. This method may obtain the additional effects of stabilizing the semiconductor layer 200 and decreasing the resistance without a change in the layer quality.

In addition, a metal powder 160 with a rough particle surface may be used to improve adhesion, and may be used along with the above-described method to maximize the adhesive force. More specifically, the metal powder 160 may contain one of silver (Ag), aluminum (Al), titanium (Ti), and alloys thereof, which possess excellent electrical conductivity and reflectance. Said metal powder 160 containing silver, aluminum, titanium, or alloys thereof would consist of particles with sizes in the range of 50 nm to 5 μm, and said particles of the metal powder 160 would be uniformly distributed in order to uniformly reflect the light of the region of the wide wavelength.

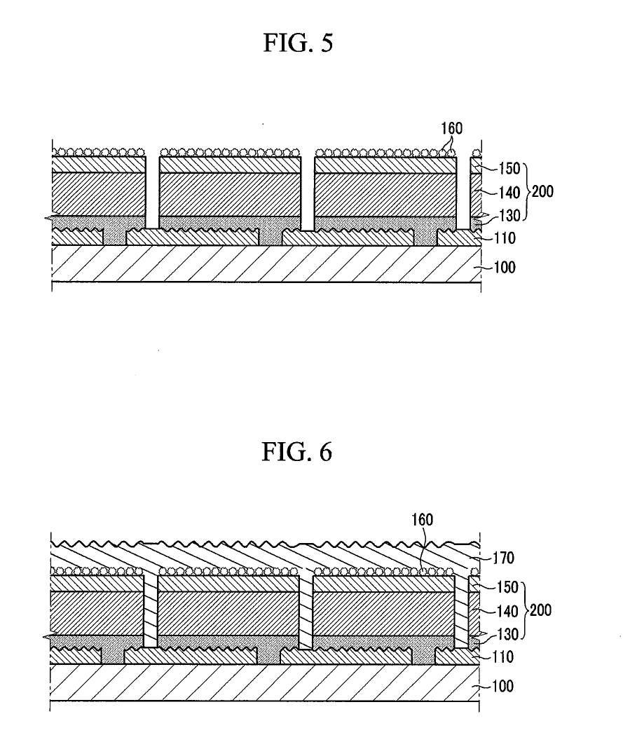

Next, as shown in FIG. 5, the semiconductor layer 200 is patterned by laser scribing. The P layer 130, the I layer 140, and the N layer 150 that are sequentially deposited to form the semiconductor layer 200 are patterned in this process, as well as the metal powder 160. Before patterning, a transparent conductive layer (not shown) may be formed on the semiconductor layer 200 and the metal powder 160, and the upper surface of the transparent conductive layer may be textured to increase solar cell efficiency. Forming the transparent conductive layer and texturing the upper surface of the transparent conductive layer may be omitted.

Next, as shown in FIG. 6, a rear electrode layer 170 is deposited on the semiconductor layer 200 and the metal powder 160. Here, the thickness of the rear electrode layer 170 may be in the range of 2000 Å to 4000 Å.

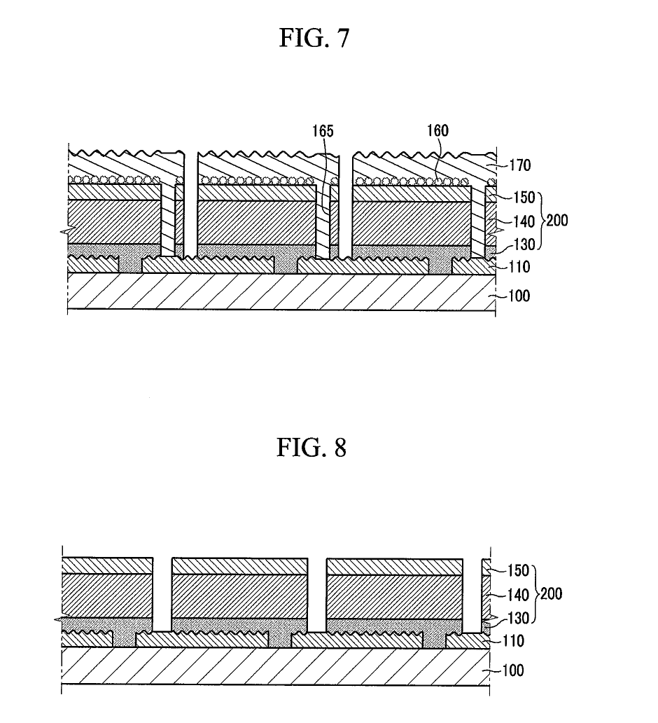

Next, as shown in FIG. 7, the rear electrode layer 170, the metal powder 160, and the semiconductor layer 200 are patterned by laser scribing.

The solar cell manufactured by the above-described method maximizes reflectance of the rear reflecting electrode layer without requiring the deposition and texturing of a rear transparent conductive layer between the semiconductor layer 200 and the rear electrode layer 170. Diffused reflection is generated in the portion where the metal powder 160 is attached such that the path of the reflected light is increased.

FIG. 8 to FIG. 11 are cross-sectional views sequentially showing the manufacturing process in a method of manufacturing a solar cell according to another exemplary embodiment of the present invention.

Again referring to FIG. 1 to FIG. 3, in a method of manufacturing a solar cell according to another exemplary embodiment of the present invention, a transparent conductive layer 110 is deposited on a substrate 100, and is textured such that the surface thereof is uneven like the surface of a fabric, thereby increasing the absorption efficiency of solar light.

Next, the transparent conductive layer 110 is patterned by laser scribing.

Next, a P layer 130, an I layer 140, and an N layer 150 are sequentially deposited on the patterned transparent conductive layer 110 to form a semiconductor layer 200. The P layer 130, the I layer 140, and the N layer 150 may be deposited by plasma enhanced chemical vapor deposition (PECVD).

Next, as shown in FIG. 8, the semiconductor layer 200 is patterned by laser scribing. Before patterning, a transparent conductive layer (not shown) may be formed on the semiconductor layer 200, and the upper surface of the transparent conductive layer may be textured to increase solar cell efficiency. Forming the transparent conductive layer and texturing the upper surface of the transparent conductive layer may be omitted.

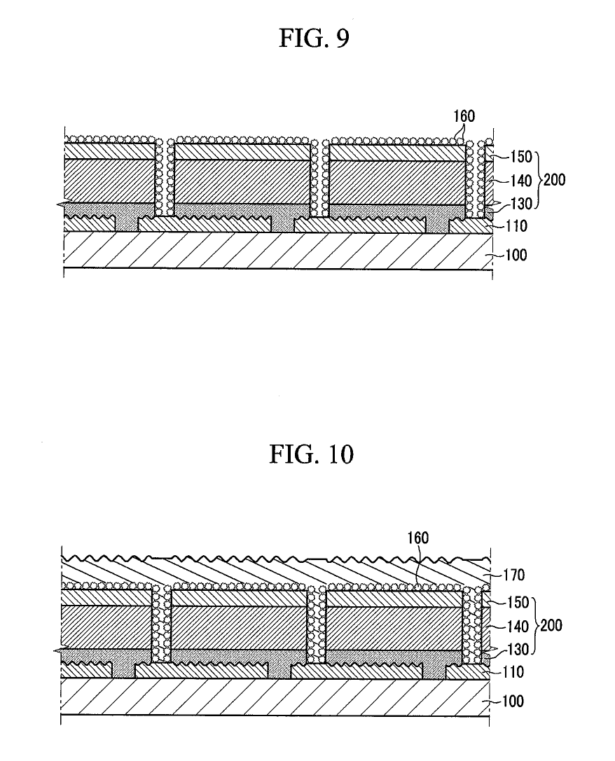

Next, as shown in FIG. 9, a metal powder 160 is coated on the patterned semiconductor layer 200. Here, the metal powder 160 covers the upper surface and the lateral surfaces of the patterned semiconductor layer 200.

The method used to coat the semiconductor layer with the metal powder 160 may be one of spin coating, slit coating, spraying, screen printing, ink-jetting, gravure printing, offset printing, and dispensing. To coat the metal powder 160 on the semiconductor layer 200 by using these methods, the metal powder 160 is dispersed in a solvent having high volatility so as not to affect the metal power 160 and the different layers, and is coated as a solution, a paste, or an ink on the semiconductor layer 200.

The dispersion agent used to coat the metal powder 160 on the semiconductor layer 200 may be an amphiphilic solvent or surfactant. The amphiphilic solvent or surfactant is a material that is simultaneously hydrophilic and hydrophobic such that the characteristics of the material are determined according to the peripheral environments.

The amphiphilic solvent or surfactant may be ethanol, methanol, acetone, isopropyl alcohol, N-methyl pyrrolidone (NMP), cyclopentanone, or cyclohexanone. Among them, N-methyl pyrrolidone (NMP), cyclopentanone, or cyclohexanone may be preferred.

Here, the amphiphilic solvent or surfactant may function as a hydrophilic solvent, whereby the metal powder 160 is mixed with the hydrophilic solvent so as to enclose the surface of the particles of the metal powder 160 with the hydrophilic solvent, such that the metal powder 160 may be easily adsorbed onto the surface of the semiconductor layer 200, and also that the metal powder 160 particles do not coagulate.

To improve the adsorption of the metal powder 160 onto the semiconductor layer 200, the following method may be applied.

Before coating the metal powder 160, the semiconductor layer 200 is irradiated with hydrogen plasma or argon plasma to form protrusions and depressions on the surface of the semiconductor layer 200.

Adhesion force may be improved by using an adhesion promoter or an additive that does not have an interaction reaction with the semiconductor layer 200 and the metal powder 160.

Also, before coating the metal powder 160, the semiconductor layer 200 may be heat-treated for a short time (e.g., less than 30 minutes) at a low temperature (e.g., less than 200 degrees) to increase the adhesion force. This method may obtain the additional effects that the semiconductor layer 200 is stabilized and the resistance is decreased without a change in the layer quality.

In addition, a metal powder 160 with a rough particle surface may be used to improve the adhesion force, and may be used along with the above-described method to maximize the adhesion force. More specifically, the metal powder 160 may contain one of silver (Ag), aluminum (Al), titanium (Ti), and alloys thereof, which possess excellent electrical conductivity and reflectance. Said metal powder 160 containing silver, aluminum, titanium, or alloys thereof would consist of particles with sizes in the range of 50 nm to 5 μm, and said particles of the metal powder 160 would be uniformly distributed in order to uniformly reflect the light of the region of the wide wavelength.

Next, as shown in FIG. 10, a rear electrode layer 170 is deposited on the semiconductor layer 200 and the metal powder 160. Here, the thickness of the rear electrode layer 170 may be in the range of 2000 Å to 4000 Å.

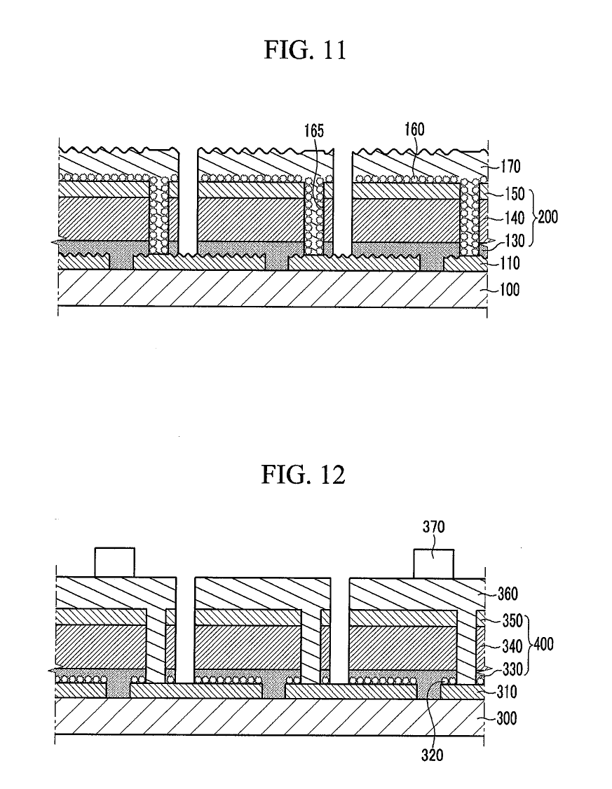

Next, as shown in FIG. 11, the rear electrode layer 170, the metal powder 160, and the semiconductor layer 200 are patterned by laser scribing.

In the solar cell manufactured by the above-described method, the metal powder 160 is attached to the lateral surface of the semiconductor layer 200 as a light absorption layer such that the light incident from the lateral side and the reflected light in the inner portion are diffusely reflected by the metal powder 160, as well as the light incident in the vertical direction. Accordingly, the path of the light entering the solar cell is lengthened such that the light absorption is increased, thereby improving the light absorption efficiency. Furthermore, a highly-efficient reflection layer is formed without the need for deposition of the rear transparent conductive layer, which reduces the number of manufacturing processes involved and therefore the process cost, as well as reducing or eliminating loss due to the low electrical conductivity of the rear transparent conductive layer relative to the rear electrode layer 170, and avoiding the contact resistance generated by additional contact interfaces between layers.

Again referring to FIG. 7 and FIG. 11, a solar cell according to another exemplary embodiment of the present invention will be described.

As shown in FIG. 7, a transparent conductive layer 110 is deposited on a substrate 100. The upper surface of the transparent conductive layer 110 may be textured. A semiconductor layer 200 having a P layer, an I layer, and an N layer that are sequentially deposited is formed on the transparent conductive layer 110. A metal powder 160 is coated on the semiconductor layer 200. The semiconductor layer 200 and the metal powder 160 are patterned to form a contact hole 165. A rear electrode layer 170, which fills in the contact hole, is formed on the semiconductor layer 200 and the metal powder 160.

Referring to FIG. 11, in contrast to FIG. 7, the metal powder 160 is coated on the lateral surface of the semiconductor layer 200 which is exposed after formation of the contact hole 165. Accordingly, the light incident from the lateral surface is reflected, thereby increasing the light absorption efficiency.

The solar cell according to an exemplary embodiment of the present invention may be a substrate type of a metal/N—I—P/TCO/grid structure mainly using an opaque metal plate, as well as a superstrate type of a TCO/P—I—N/metal structure using a glass material. Hereafter, referring to FIG. 12, a solar cell applied with a substrate type according to an embodiment of the present invention will be described in detail.

Referring to FIG. 12, a solar cell of a substrate type according to an embodiment of the present invention includes a reflecting electrode 310 deposited on a substrate 300.

A transparent conductive layer(not shown) may be formed on the reflecting electrode 310. A semiconductor layer 400 is disposed on the reflecting electrode 310. The semiconductor layer 400 includes a N layer 330, an I layer 340, and a P layer 350 sequentially deposited on the reflecting electrode 310.

Metal powder 320 is coated between the the reflecting electrode 310 and the semiconductor layer 400, thereby increasing the reflectance of the reflecting electrode 310.

A transparent conductive layer 360 is disposed on the the semiconductor layer 400. A connection electrode 370 that is patterned may be further disposed on the transparent conductive layer 360.

The substrate 300 may be made of an opaque metal foil.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a solar cell, comprising:
depositing a transparent conductive layer on a substrate;
patterning the transparent conductive layer;
forming a semiconductor layer deposited on the patterned transparent conductive layer;
patterning the semiconductor layer;
coating the patterned semiconductor layer with metal powder after the patterning of the semiconductor layer;
forming a rear electrode layer on the semiconductor layer coated with the metal powder; and
patterning the rear electrode layer and the semiconductor layer.

2. The method of claim 1, wherein
in the coating of the metal powder on the patterned semiconductor layer, the metal powder covers the upper surface and the lateral surface of the patterned semiconductor layer.

3. The method of claim 2, wherein
the metal powder is one of silver (Ag), aluminum (Al), titanium (Ti), and alloys thereof.

4. The method of claim 3, wherein
the metal powder is made up of particles whose sizes range from 50 nm to 5 μm.

5. The method of claim 4, wherein:
the metal powder is dispersed in a volatile solvent and coated as a solution, a paste, or an ink on the semiconductor layer.

6. The method of claim 1, wherein
the coating of the metal powder on the patterned semiconductor layer is accomplished through use of at least one of spin coating, slit coating, spraying, screen printing, ink-jetting, gravure printing, offset printing, and dispensing.

7. The method of claim 1, wherein,
in the coating of the metal powder on the patterned semiconductor layer, the metal powder is mixed with an amphiphilic solvent or surfactant and coated on the semiconductor layer.

8. The method of claim 7, wherein
the amphiphilic solvent or surfactant is one of ethanol, methanol, acetone, isopropyl alcohol, N-methyl pyrrolidone (NMP), cyclopentanone, and cyclohexanone.

9. The method of claim 1, wherein,
before the coating of the metal powder on the patterned semiconductor layer, the semiconductor layer is irradiated by plasma to form protrusions and depressions on the surface of the semiconductor layer.

10. The method of claim 1, wherein,
before the coating of the metal powder on the patterned semiconductor layer, the semiconductor layer is heat-treated.

11. The method of claim 10, wherein
the heat treatment is executed at a temperature of less than 200 degrees and for a time of less than 30 minutes.

12. The method of claim 1, wherein,
before the coating of the metal powder on the patterned semiconductor layer, the semiconductor layer is coated with an adhesive.

13. The method of claim 1, wherein,
before the patterning of the transparent conductive layer, the upper surface of the transparent conductive layer is textured.

14. A method of manufacturing a solar cell, comprising:
depositing a transparent conductive layer on a substrate;
patterning the transparent conductive layer;
forming a semiconductor layer deposited on the patterned transparent conductive layer;
coating the semiconductor layer with metal powder;
patterning the semiconductor layer after coating the semiconductor layer with the metal powder;
forming a rear electrode layer on the patterned semiconductor layer; and
patterning the rear electrode layer and the semiconductor layer.

15. The method of claim 14, wherein,
before patterning the transparent conductive layer, the upper surface of the transparent conductive layer is textured.

16. The method of claim 14, wherein,
in the coating of the metal powder on the semiconductor layer, the metal powder is mixed with an amphiphilic solvent or surfactant and the semiconductor layer is coated with the metal power.

17. The method of claim 16, wherein
the amphiphilic solvent or surfactant is one of ethanol, methanol, acetone, isopropyl alcohol, N-methyl pyrrolidone (NMP), cyclopentanone, and cyclohexanone.

18. A solar cell comprising:
a substrate;
a transparent conductive layer deposited on the substrate;
a semiconductor layer deposited on the transparent conductive layer;
metal powder coated on the semiconductor layer;
a contact hole formed in the semiconductor layer; and
a rear electrode layer filling in the contact hole and covering the semiconductor layer.

19. The solar cell of claim 18, wherein
the metal powder is coated on the lateral surface of the semiconductor layer exposed by the contact hole.

20. The solar cell of claim 19, wherein
the metal powder is made of one of gold, aluminum, titanium, and alloys thereof.

21. The solar cell of claim 20, wherein
the metal powder is mixed with an amphiphilic solvent or surfactant and coated on the semiconductor layer.

22. The solar cell of claim 18, wherein the semiconductor layer includes a P layer, an I layer, and an N layer.

23. A solar cell comprising:
a substrate;
a reflecting electrode layer deposited on the substrate;
metal powder coated on the reflecting electrode layer;
a semiconductor layer deposited on the reflecting electrode layer coated with the metal powder, wherein the semiconductor layer includes an N layer, an I layer, and a P layer; and
a rear electrode layer deposited on the semiconductor layer.

24. A solar cell of claim 23, wherein
a connection electrode is formed on the rear electrode layer.
